(19) United States
(12) Patent Application Publication
(10) Pub. No.: US 2008/0156475 A1
(43) Pub. Date: Jul. 3, 2008

(54) Thermal interfaces in electronic systems

(76) Inventor: Daewoong Suh, Phoenix, AZ (US)

Correspondence Address: CAVEN & AGHEVLI;c/o INTELLEVATE, LLC, P.O. BOX 52050, MINNEAPOLIS, MN, 55402, US

(21) Appl. No.: 11/646,887

(22) Filed: Dec. 28, 2006

(51) Int. Cl. H05K 7/20

(52) U.S. Cl. 165/185; 361/699

(57) ABSTRACT

In one embodiment, an apparatus comprises a semiconductor device, a heat dissipation assembly, and a thermal interface material disposed between the semiconductor device and the heat dissipation assembly, wherein the thermal interface layer comprises an indium alloy.

### BACKGROUND

The subject matter described herein relates generally to the field of electronic devices and more particularly to thermal interfaces in electronic systems.

Electronic components, including integrated circuits, may be assembled into component packages by physically and electrically coupling them to a substrate. During operation, the component package may generate heat that can be dissipated to help maintain the circuitry at a desired temperature. Heat sinks, heat spreaders, and other heat dissipating elements may be attached to the package via a suitable thermal interface material.

Thermal interface materials have been made from Indium. Additional materials to make thermal interface materials may find utility.

### BRIEF DESCRIPTION OF THE DRAWINGS

The detailed description is described with reference to the accompanying figures.

FIG. 1 is a cross-sectional, schematic illustration of an electronic device adapted to accommodate a thermal interface in accordance with some embodiments.

FIG. 2 is a schematic illustration of a thermal interface material in accordance with some embodiments.

FIGS. 3A-3C are schematic illustrations of transient liquid phase sintering (TLPS) in accordance with some embodiments.

FIGS. 4A-4C are schematic illustrations of TPLS paste designs in accordance with some embodiments.

FIG. 5 is a schematic illustration of a computing system which may incorporate a thermal interface in accordance with some embodiments.

### DETAILED DESCRIPTION

Described herein are exemplary thermal interfaces which may be used in electronic system such as, e.g., computing systems. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

In some embodiments the thermal interfaces described herein may be implemented to transfer heat from surfaces of electronic components such as, e.g., integrated circuits (ICs). In alternate embodiments the thermal interfaces described herein may be implemented to transfer heat in any setting where heat is to be conducted from one surface to another. For ease of explanation, the example of cooling an IC will be described.

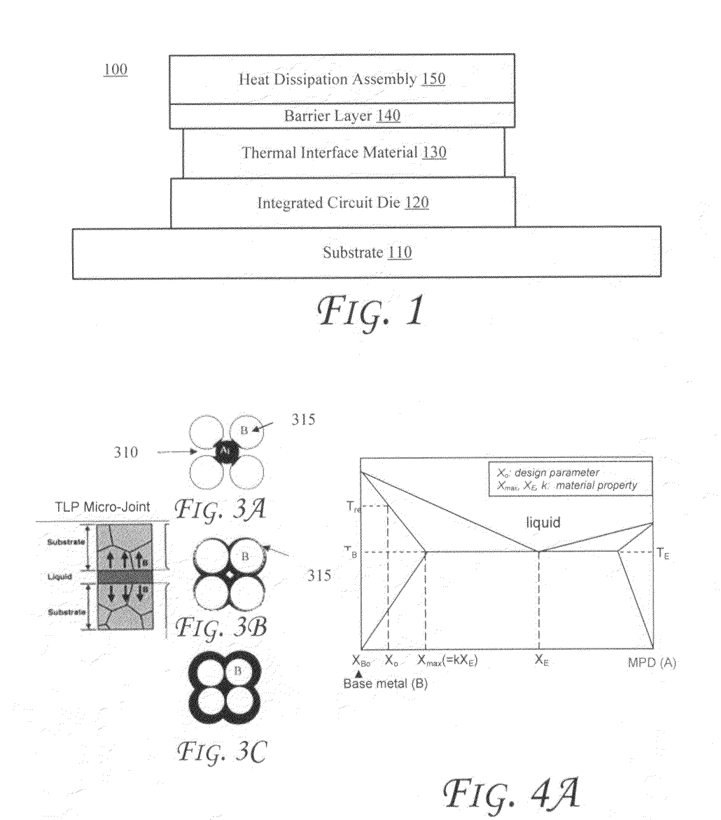

FIG. 1 is a cross-sectional, schematic illustration of an electronic device adapted to accommodate a thermal interface in accordance with some embodiments. Referring to FIG. 1, electronic device 100 includes an IC die 120 coupled to an upper surface of a substrate 110, such as a circuit board. Substrate 110 can be a one-layer circuit board or a multi-layer circuit board.

IC die 120 generates its heat from internal structure, including wiring traces. Heat generated by IC die 120 may be dissipated by a heat dissipation assembly 150. In some embodiments, heat dissipation assembly 150 may include a heat sink to dissipate heat into the ambient environment. The heat sink may be active, i.e., it may utilize one or more fans to dissipate heat, or passive, i.e., it may rely on convection to dissipate heat. In some embodiments, heat dissipation assembly 150 may include a heat pipe assembly that utilizes a fluid such as, e.g., water or oil, to dissipate heat generated by the integrated circuit die 120.

A thermal interface material 130 is disposed between the integrated circuit die 120 and the heat dissipation assembly 150 to establish a thermal pathway between the integrated circuit die 120 and the heat dissipation assembly 150. In some embodiments, thermal interface material 130 comprises at least one of an indium alloy, an indium-tin alloy, an indium-silver alloy, a boron-nitride compound, or a lead-tin alloy. Thermal interface material may include a polymer base such as, e.g., a grease, a gel, or a precious-metal clay (PMC).

A barrier layer 140 is disposed between the thermal interface material 130 and the heat dissipation assembly 150. Barrier layer 140 may be formed from a material such as, e.g., nickel, which inhibits intermetallic interaction between the heat dissipation assembly 150 and the thermal interface material 130. In some embodiments, barrier layer 140 may be formed as a separate structural element, which may be positioned between thermal interface material 130 and heat dissipation assembly 150. In some embodiments, barrier layer 140 may be coated onto a surface of either (or both) of thermal interface material 130 or heat dissipation assembly 150, e.g., by nickel plating, dipping, brushing, coating, or depositing a layer of nickel onto the surface.

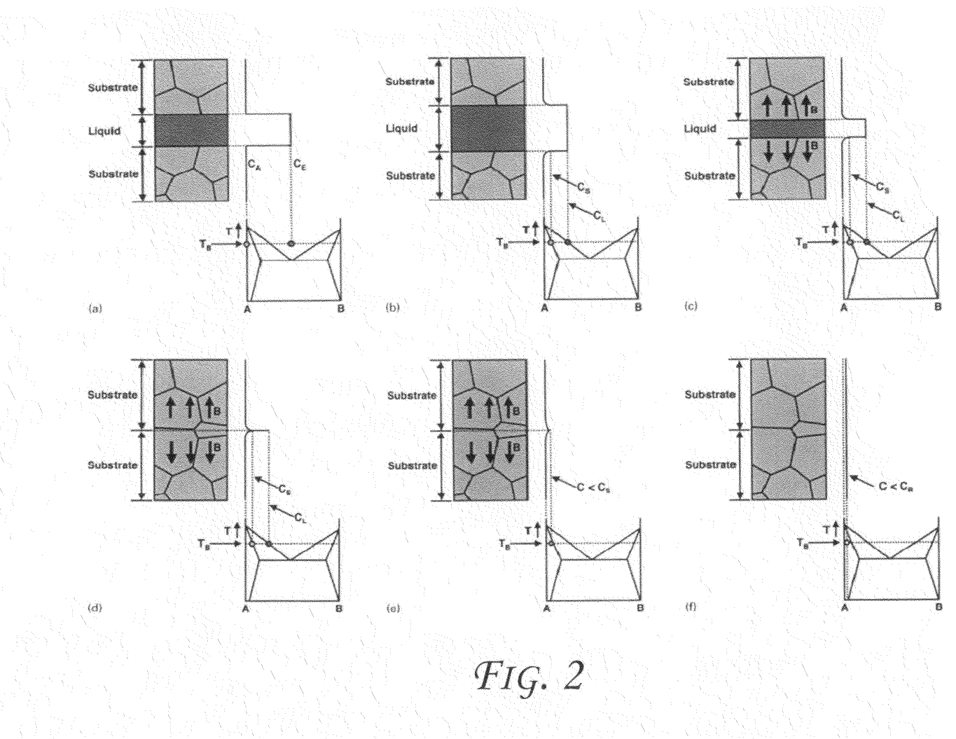

FIG. 2 is a schematic illustration of a thermal interface material in accordance with some embodiments. Transient liquid phase bonding involves low melting temperature (Tm) interlayer sandwiched between two base metals. The low Tm interlayer has a melting point depressant (MPD) and because of that it has lower Tm than the base metal. In the schematic below, element B is MPD and eutectic A-B alloy is low Tm interlayer and A is base metal to be joined by interlayer.

At bonding temperature above Tm of the interlayer, the interlayer melts and base metal does not. After dissolution of base metal into molten interlayer, the solid (i.e., base metal) and liquid (i.e., molten interlayer) equilibrium is reached and the concentration of MPD is given by an equilibrium phase diagram. Due to interdiffusion of MPD (or B) into base metal, which occurs because the overall equilibrium composition of base metal and interlayer system is smaller in B than original composition of interlayer, the liquid phase become diminished. This is because MPD is being depleted in liquid phase but due to thermodynamic equilibrium between base metal and interlayer, liquid concentration is maintained. Eventually all MPD is diffused to the base metal and isothermal solidification is achieved. Depending on original composition and bonding temperature/time, Tm of final composition is typically higher than original Tm of interlayer, leading to higher remelting temperature.

Liquid phase sintering (LPS) is a type of sintering process involving reactive liquid phase which can dissolve some solid particle in it and wet on the solid particle. High Tm powder and low Tm powder are mixed together and at sintering temperature, only low Tm powder melts. Once the liquid phase wets high Tm powder, each inter-particle space becomes a capillary in which a substantial capillary pressure is developed. The capillary pressure can aid sintering or densification process via various mechanisms such as, for example, rearrangement of solid particle for more effective packing, plastic deformation/creep at contact for more effective packing, solution of smaller particles and growth of larger particles by liquid-state diffusion, enhanced solubility in liquid phase and material transfer away from contact leading to shrinkage. Because of this capillary pressure-aided densification, more effective sintering is achieved.

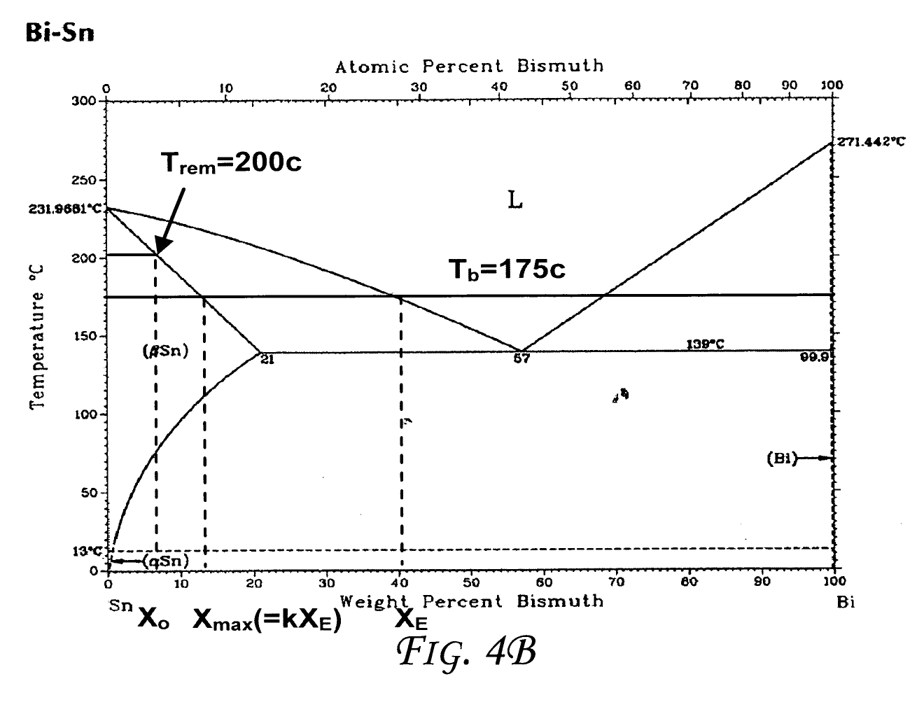

FIGS. 3A-3C are schematic illustrations of transient liquid phase sintering (TLPS) in accordance with some embodiments. TLPS is a combination of TLP bonding and LPS. It involves a mixture of low Tm powder 310 and high Tm powder 315. In TLPS, low Tm powder 310 corresponds to interlayer in TLP and High Tm powder 315 corresponds to Base metal in TLP.

Bonding at temperature above Tm of Low Tm powder enables the following processes: low Tm powder melts, liquid spreading by capillary reaction, at each interface between High Tm powder filled with liquid serves as “micro-TLP joint” and isothermal solidification 320 occurring at each interface between high Tm powder and liquid phase (FIG. 3B), and capillary pressure-aided sintering.

After bonding, densification is achieved with higher remelting temperature (FIG. 3C). Because of significantly reduced diffusion distance of MPD (i.e., MPD only has to diffuse over a few microns between High Tm powder), TLP process in TLPS system is much faster.

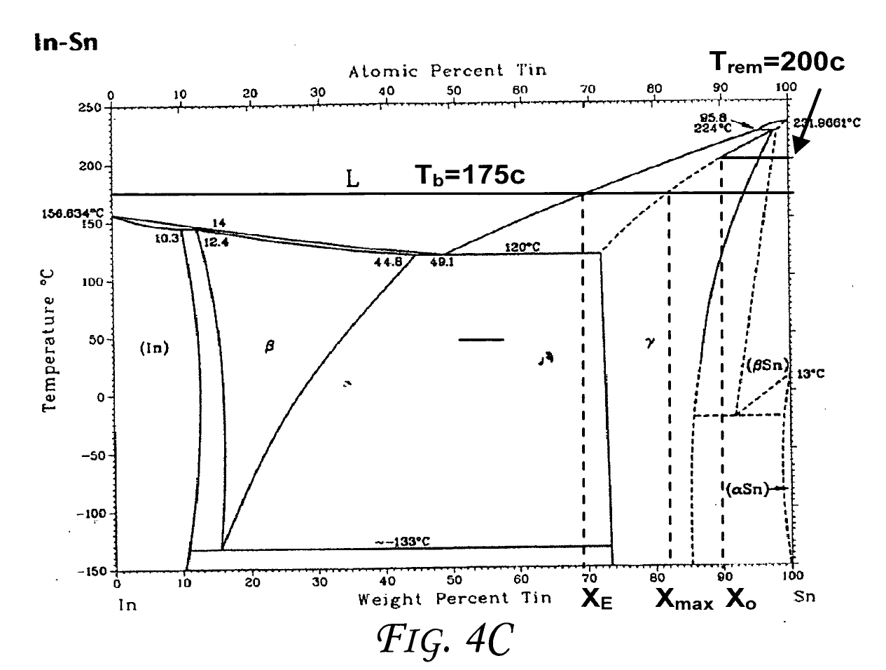

FIGS. 4A-4C are schematic illustrations of TPLS paste designs in accordance with some embodiments. FIG. 4A is an example of TLPS Paste Design. This example shows that a low bonding temperature (175 C) can be achieved with high remelting temperature (200 C) with no indium or with approximately 10% indium.

FIG. 4B is a schematic depiction of a Tin-Bismuth (Sn—Bi) system. Based on this, TLPS paste design parameters are as follows for bonding temperature of 175 and remelting temperature of 200 C, for example:
High Tm base metal
   Pure Sn
Low Tm phase
   Eutectic Sn-58% Bi (Tm=138 C)
Bonding parameters
   Bonding temp=175 C
   Remelting temp=200 C
Initial liquid phase weight fraction
   0.16
Paste design
   High Tm powder: Sn (84 wt. %)
   Low Tm powder: eut. Sn—Bi (16 wt. %)
   Final composition after bonding: Sn-6.5% Bi

FIG. 4C is a schematic depiction of a Tin-Bismuth (Sn—In) system. Based on this, TLPS paste design parameters are as follows for bonding temperature of 175 and remelting temperature of 200 C, for example:
High Tm base metal
   Pure Sn
Low Tm phase
   Eutectic Sn-52% In (Tm=118 C)
Bonding parameters
   Bonding temp=175 C
   Remelting temp=200 C
Initial liquid phase weight fraction
   0.32
Paste design
   High Tm powder:Sn (68 wt. %)
   Low Tm powder: eut. Sn—In (32 wt. %)
   Final composition after bonding: Sn-10% In

In one embodiment, the techniques described herein may be used to form a TLP “preform”. This preform can be used in stead of a pure indium preform. The preform may be sandwiched between heat spreader and Si die and bonded at a certain bonding temperature above Tm of TLP preform for a certain bonding time. After bonding is completed, the resultant joint has higher remelting temperature than the original Tm of TLP preform.

In one embodiment a TLP perform may use a Sn-In-Bi system as a baseline. Various compositions may be used provided the liquidous of the compositions is low enough (e.g., between 232 to 110 C). For example:
Sn-xIn-zZn(x=0 to 80%, z=0 to 10%)
Sn-xBi-zZn (x=0 to 60%, z=0-10%)
Sn-xIn-yBi-zZn (x=0 to 80%, y=0 to 60%, z=0 to 10%; x+y+z+Sn content=100%)

In some embodiments a small amount of Ag can be added optionally (e.g., less than 5%).

In order to get acceptable Rjc after TLP bonding, preform thickness may need to be adjusted. Given the thermal conductivity of the final TLP joint, the maximum TLP preform thickness (PFT) may be calculated using the following formula. The TLP preform can typically range from 3 mil to 7 mil.

The embodiment may utilize a surface finish on back side die or heat spreader. For example, Sn is ideal surface finish because Sn can absorbe In, Bi, Zn without forming IMC which detrimental to TLP processes. Cu or Ni can be also used but its effectiveness is lower than Sn because Cu or Ni forms intermetallic compound with some of components in the joint, inhibiting free interdiffusion.

In another embodiment, the techniques describe herein may be used to form a TLPS “paste”. The paste is made up of low Tm powder and high Tm powder along with one or more additives/fluxes is dispensed on back side of Si die. Then a heat spreader is attached and bonded at a certain bonding temperature above Tm of low Tm powder (yet below Tm of High Tm powder) for a certain bonding time. After bonding is completed, the resultant joint has higher remelting temperature than the original Tm of TLPS paste. The main advantages of TLPS paste over TLP preform are i) much faster kinetics leading to much faster bonding time, and ii) less indium usage.

The example of paste design scheme is discussed above. The followings are possible compositions and weight percentages of Low Tm powder and High Tm powders. Bonding temperature is set at a certain temperature above Tm of Low Tm powder and below Tm of High Tm powder and bonding time ranges from a couple of minutes up to 2 hours.

| | | Low Tm | | |
|---|---|---|---|---|
| | Low Tm | powder | | High Tm |
| | powder | weight % | High Tm powder | powder weight % |
| Sn—In | Sn—xIn | 10 to 50% | Pure Sn, Sn—xIn (x < 30%), Sn—xBi | 90 to 50% |
| system | (x = 90 to | | (x < 40%), Sn—xIn—yBi (x = 0 to 30%, y = 0 | |
| | 30%) | | to 40%, x + y + Sn = 100%), Sn—xAg (x = 0 to | |
| | | | 25%), Sn—xCu (x = 0 to 25%), Sn—xAg—yCu | |
| | | | (x = 0 to 25%, y = 0 to 25%, x + y + Sn = 100%) | |
| Sn—Bi | Sn—xBi | 10 to 50% | Pure Sn, Sn—xBi (x < 40%), Sn—xIn | 90 to 50% |
| system | (x = 70 to | | (x < 30%), Sn—xIn—yBi (x = 0 to 30%, y = 0 | |
| | 40%) | | to 40%, x + y + Sn = 100%), Sn—xAg (x = 0 to | |
| | | | 25%), Sn—xCu (x = 0 to 25%), Sn—xAg—yCu | |
| | | | (x = 0 to 25%, y = 0 to 25%, x + y + Sn = 100%) | |

In order to get an accepteable Rjc value after bonding, Joint thickness needs to be adjusted. Given the thermal conductivity of the final joint, the maximum joint thickness (PFT) may be calculated using the following formula. The joint thickness can typically range from 3 mil to 7 mil.

The embodiment may utilize a surface finish on back side die or heat spreader. For example, Sn is ideal surface finish because Sn can absorbe In, Bi, Zn without forming IMC which detrimental to TLP processes. Cu or Ni can be also used but its effectiveness is lower than Sn because Cu or Ni forms intermetallic compound with some of components in the joint, inhibiting free interdiffusion.

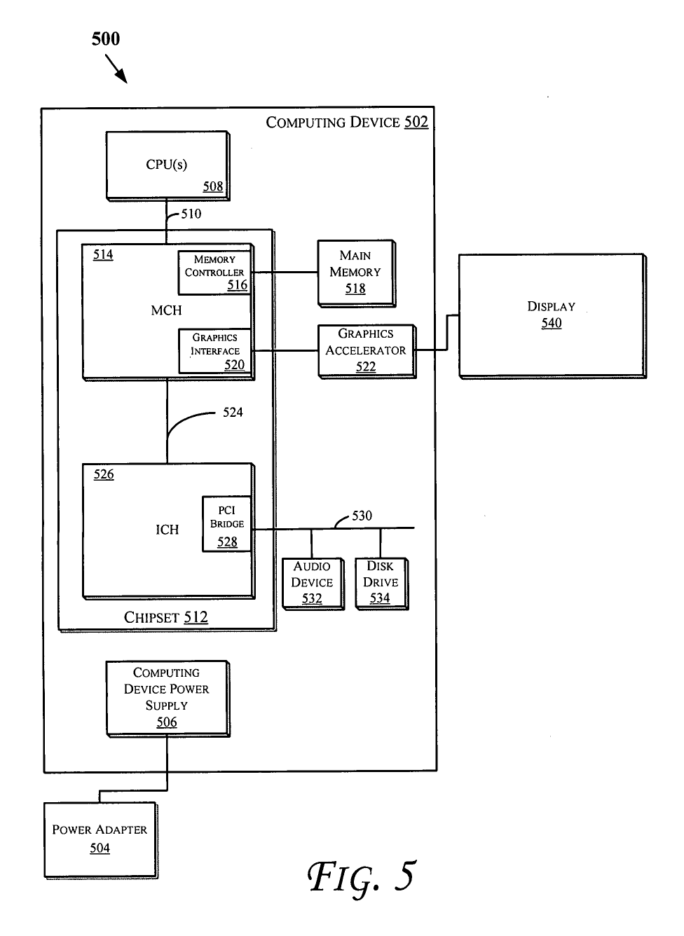

FIG. 5 is a schematic illustration of a computer system 500 in accordance with an embodiment. The computer system 500 includes a computing device 502 and a power adapter 504 (e.g., to supply electrical power to the computing device 502). The computing device 502 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 502 (e.g., through a computing device power supply 506) from one or more of the following sources: one or more battery packs, an alternating current (AC) outlet (e.g., through a transformer and/or adaptor such as a power adapter 504), automotive power supplies, airplane power supplies, and the like. In one embodiment, the power adapter 504 may transform the power supply source output (e.g., the AC outlet voltage of about 110 VAC to 240 VAC) to a direct current (DC) voltage ranging between about 7 VDC to 12.6 VDC. Accordingly, the power adapter 504 may be an AC/DC adapter.

The computing device 502 may also include one or more central processing unit(s) (CPUs) 508 coupled to a bus 510. In one embodiment, the CPU 508 may be one or more processors in the Pentium® family of processors including the Pentium® II processor family, Pentium® III processors, Pentium® IV processors available from Intel® Corporation of Santa Clara, Calif. Alternatively, other CPUs may be used, such as Intel's Itanium®, XEON™, and Celeron® processors. Also, one or more processors from other manufactures may be utilized. Moreover, the processors may have a single or multi core design.

A chipset 512 may be coupled to the bus 510. The chipset 512 may include a memory control hub (MCH) 514. The MCH 514 may include a memory controller 516 that is coupled to a main system memory 518. The main system memory 518 stores data and sequences of instructions that are executed by the CPU 508, or any other device included in the system 500. In one embodiment, the main system memory 518 includes random access memory (RAM); however, the main system memory 518 may be implemented using other memory types such as dynamic RAM (DRAM), synchronous DRAM (SDRAM), and the like. Additional devices may also be coupled to the bus 510, such as multiple CPUs and/or multiple system memories.

The MCH 514 may also include a graphics interface 520 coupled to a graphics accelerator 522. In one embodiment, the graphics interface 520 is coupled to the graphics accelerator 522 via an accelerated graphics port (AGP). In an embodiment, a display (such as a flat panel display) 540 may be coupled to the graphics interface 520 through, for example, a signal converter that translates a digital representation of an image stored in a storage device such as video memory or system memory into display signals that are interpreted and displayed by the display. The display 540 signals produced by the display device may pass through various control devices before being interpreted by and subsequently displayed on the display.

A hub interface 524 couples the MCH 514 to an input/output control hub (ICH) 526. The ICH 526 provides an interface to input/output (I/O) devices coupled to the computer system 500. The ICH 526 may be coupled to a peripheral component interconnect (PCI) bus. Hence, the ICH 526 includes a PCI bridge 528 that provides an interface to a PCI bus 530. The PCI bridge 528 provides a data path between the CPU 508 and peripheral devices. Additionally, other types of I/O interconnect topologies may be utilized such as the PCI Express™ architecture, available through Intel® Corporation of Santa Clara, Calif.

The PCI bus 530 may be coupled to an audio device 532 and one or more disk drive(s) 534. Other devices may be coupled to the PCI bus 530. In addition, the CPU 508 and the MCH 514 may be combined to form a single chip. Furthermore, the graphics accelerator 522 may be included within the MCH 514 in other embodiments.

Additionally, other peripherals coupled to the ICH 526 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 502 may include volatile and/or nonvolatile memory.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” “some embodiments” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. An apparatus, comprising:
a semiconductor device; and
a heat dissipation assembly; and
a thermal interface material disposed between the semiconductor device and the heat dissipation assembly, wherein the thermal interface layer comprises an indium alloy.

2. The apparatus of claim 1, wherein the thermal interface material is formed as a transient liquid phase preform.

3. The apparatus of claim 2, wherein the thermal interface comprises an at least two of indium, tin, and bismuth.

4. The apparatus of claim 2, wherein the thermal interface comprises an at least two of indium, tin, and zinc.

5. The apparatus of claim 1, wherein the thermal interface material is formed as a transient liquid phase sintering paste.

6. The apparatus of claim 5, wherein the thermal interface comprises an at least two of indium, tin, and bismuth.

7. The apparatus of claim 5, wherein the thermal interface comprises an at least two of indium, tin, and zinc.

8. A system, comprising:
a display;
a processor coupled to a printed circuit board;
a heat dissipation assembly;
a semiconductor device;
a heat dissipation assembly; and
a thermal interface material disposed between the semiconductor device and the heat dissipation assembly, wherein the thermal interface layer comprises an indium alloy.

9. The system of claim 8, wherein the thermal interface material is formed as a transient liquid phase preform.

10. The system of claim 9, wherein the thermal interface comprises an at least two of indium, tin, and bismuth.

11. The system of claim 9, wherein the thermal interface comprises an at least two of indium, tin, and zinc.

12. The system of claim 8, wherein the thermal interface material is formed as a transient liquid phase sintering paste.

13. The system of claim 12, wherein the thermal interface comprises an at least two of indium, tin, and bismuth.

14. The system of claim 12, wherein the thermal interface comprises an at least two of indium, tin, and zinc.
